(19) United States
(12) Patent Application Publication
(10) Pub. No.: US 2026/0304666 A1
(43) Pub. Date: Oct. 1, 2026

(54) LATCH MECHANSIM FOR RELEASABLY SECURING RISER CARD ASSEMBLY

(71) Applicant: Aivres Systems Inc., San Jose, CA (US)

(72) Inventor: Cheng-Hua CHEN, New Taipei City (TW)

(21) Appl. No.: 19/097,489

(22) Filed: Apr. 1, 2025

(51) Int. Cl. H05K 7/14; H05K 5/02; H05K 7/10

(52) U.S. Cl. CPC H05K 7/1402; H05K 5/0221; H05K 7/10; H05K 7/1417; H05K 7/1435

(57) ABSTRACT

An arrangement for stably and releasably securing a riser card assembly in a computer system can utilize one or more latch mechanisms. The riser card assembly may include a riser card bracket having one or more latch pins extending perpendicularly to an installation direction of the riser card assembly to the computer system. The latch mechanisms may include a latch cover defining a latch compartment accessible by a latch passageway. The latch mechanism can include a spring-load actuator with a catch to retain the latch pin when moved into the latch passageway and a spring-loaded stopper arranged to restrain movement of the spring-loaded actuator.

### TECHNICAL FIELD

This patent application relates to components for computing systems and, in particular, to a latch mechanism to lock and release printed circuit cards with respect to a chassis.

### BACKGROUND

Many computer systems, and particularly servers communicatively connected to a computer network to provide functionality and resources for other systems, are modularly designed for flexibility and scalability. For example, conventional computer systems include a motherboard or mainboard onto which are mounted the core computing components such as processors and main memory. To add additional functionality, one or more special purpose add-in cards or expansion cards can be electrically connected to the motherboard to interact with the core components. For example, the expansion cards can be designed to provide additional processing capabilities such as a graphics processing unit, increase data storage, and modify or improve networking capabilities and communications. To facilitate adaptability and modularity, motherboards typically include one or more board-mounted expansion sockets that are often configured as edge connectors having an elongated slot that receives the border or edge of an expansion card on which conductive traces are exposed.

The planar motherboard is usually positioned horizontally in the chassis of the computer system with the expansion card sockets oriented upwards. As such, when the expansion cards are connected to the expansion sockets, the expansion cards project vertically upwards and perpendicularly from the motherboard. If the computer system is configured as a data server or network server, which may be accommodated in a vertical rack with other computer systems located above and below it, the heigh dimensions of the chassis may be limited. Moreover, when the computer system is functioning as a server, it may be desired to add more expansion cards to the computer system than there is corresponding number of expansion card sockets on the motherboard.

To address the space and capacity restraints, riser cards may be used to function as an intermediate connector between the expansion cards and the motherboard, allowing the expansion cards and the motherboard to be indirectly connected. The planar riser card may be shorter than the corresponding expansion cards and may include a plurality of card-mounted expansion sockets oriented horizontally to receive the expansion cards. The expansion cards therefore extend parallel to the planar orientation of the motherboard, which allows larger or longer expansion cards to be used.

### SUMMARY OF THE DISCLOSURE

To securely install a riser card assembly within a computer system, the disclosure provides a latching arrangement including one or more latching mechanisms that can be mounted to a chassis panel and are adapted to selectively lock and release with the riser card assembly. The riser card assembly may include a planar riser card configured to be installed to a board-mounted expansion socket in an installation direction and a riser card bracket including a latch pin extending in a lateral direction perpendicular to the installation direction. The latch mechanism may include a latch cover having a latch passageway disposed therein that is accessible from the installation direction. Located in the latch cover is a spring-loaded actuator defining a catch and detent. The catch is configured to receive and retain the latch pin when moved into the latch passageway and the detent is engageable with a spring-loaded stopper to arrest movement of the spring-loaded actuator.

In a further aspect, the spring-loaded actuator comprises a latch rotor having a rotational axis aligned parallel to the lateral direction.

In a further aspect, the spring-loaded actuator comprises a torsion spring having a helical coil concentric to the rotational axis and a pair of angular-spaced spring legs including a static leg and a deflecting leg.

In a further aspect, the latch rotor comprises a rotor periphery, and the static leg extends beyond the rotor periphery to abut the latch cover.

In a further aspect, the deflecting leg extends to and is retrained at the rotor periphery.

In a further aspect, the catch comprises a pair of bifurcated cog prongs that angularly diverge from each other.

In a further aspect, the pair of bifurcated cog prongs normally passes through the latch passageway when the spring-loaded actuator is released.

In a further aspect, the latch compartment extends along a compartment axis and the latch passageway is orthogonal to the compartment axis.

In a further aspect, the spring-loaded stopper is biased to translate in parallel along the compartment axis.

In a further aspect, the spring-located stopper includes one or more coils springs having a deflection axis parallel to the compartment axis.

In a further aspect, the spring-loaded stop includes a plunger prong shaped to be received in the detent.

In a further aspect, the riser card bracket includes an I/O window brace and a chassis mounting support perpendicularly intersected to each other and the latch pin is attached to the chasing mounting support.

In a further aspect, the riser card comprises one or more card-mounted expansion sockets that define a second installation direction parallel to the lateral direction and perpendicular to the first installation direction.

The disclosure also provides a method of installing a riser card assembly in a computer system using a lockable and releasable latch arrangement. The method includes attaching a riser card to a riser card bracket to produce a riser card assembly. The riser card bracket may include one or more latch pins that extend in a lateral direction. To connect the riser card with a board-mounted connector socket, the riser card assembly is moved in an installation direction associated with the board-mounted connector socket. Concurrently, the latch pin is inserted into a latch passageway of the latch mechanism to actuate a spring-loaded actuator located therein, thus retaining the latch pin. To lock and prevent unintentional release of the latch pin, a spring-loaded stopper is urged against the spring-loaded actuator to arrest and restrain further movement of the actuator.

In a further aspect, the latch pin is inserted into the latch passageway in the installation direction.

In a further aspect, the spring-loaded stopper is biased to translate along a compartment axis of the latch mechanism orthogonal to the installation direction.

In a further aspect, the spring-loaded actuator includes a torsion spring having a static leg and a deflecting leg that are angularly compressible to each other during installation.

In a further aspect, wherein the method further comprises connecting an expansion card to a card-mounted expansion socket by moving the expansion card in the lateral direction.

In another aspect, the disclosure provides a latch mechanism for installing printed circuit cards in a computer system. The latch mechanism includes a latch cover defining a latch compartment extending along a compartment axis that is accessible by a latch passageway orthogonal to the latch axis. Located in the latch compartment are a spring-loaded actuator having a catch configured to receive and retain a latch pin moved into the latch passageway and a spring-loaded stopper moveable within the latch compartment along the latch axis. The spring-loaded stopper is adapted to urge against the spring-loaded actuator and engage a detent to restrain the actuator.

In a further aspect, the spring-loaded actuator includes a latch rotor having circular periphery with the catch and the detent located on the circular periphery, and the spring-loaded actuator further includes a torsion spring having a rotational axis orthogonal to latch axis to rotate the latch rotor. The spring-loaded stopper may include a plunger prong shaped to be received in the detent and the one or more coil springs having a deflection axis parallel to the compartment axis to urge the plunger prong against the rotor periphery

A possible advantage of the disclosure enables an increase in the capacity of computer system to accommodate a greater number of expansion cards to extend functionality. Another possible advantage is that the riser card assembly can be installed using the latching mechanisms without additional tools or fasteners. Another possible advantage is that the latching mechanism can securely and firmly hold the riser card assembly within the chassis while readily allowing for release and removal of the riser card assembly.

### BRIEF DESCRIPTION OF THE DRAWINGS

FIG. 1 is a perspective view of a computer system including a plurality of expansion cards situated parallel with respect to a motherboard by a riser card bracket mounted to the chassis through a latching arrangement in accordance with the disclosure.

FIG. 2 is a perspective view of the computer system with the riser card assembly disconnected and removed from a board-mounted connector socket associated with an installation direction and showing a pair of latch mechanisms mounted to the chassis panel.

FIG. 3 is an exploded perspective view of the riser card assembly including a riser card attachable to a riser card bracket that has a pair of latch pins extending laterally therefore.

FIG. 4 is a perspective view of the latch mechanism showing a latch cover accessible through a latch passageway from which extends the catch of the spring-loaded actuator.

FIG. 6 is a perspective view of the latch mechanism showing the spring-loaded actuator and the spring-loaded stopper accommodated in a latch compartment.

FIG. 7 is an exploded view of the latch mechanism including a latch cover accommodating a spring-loaded having a catch to receive and retain the latch pin and a spring-loaded stopper to restrain movement of the spring-loaded actuator.

FIG. 7 is a perspective view of the riser card assembly being installed on the motherboard of the computer system by a pair of latch mechanisms mounted to the chassis.

FIG. 8 is a schematic view of the latch pin on the riser card assembly interacting with the catch of the latch mechanism when in the released state during installation.

FIG. 9 is a schematic view of the latch pin retrained by the catch of the latch mechanism and rotation of the spring-loaded actuator restrained by the spring-loaded stopper when in the locked state.

FIG. 10 is a perspective view of the riser card assembly installed and locked to the motherboard of the computer system by the pair of latch mechanisms mounted to the chassis.

### DETAILED DESCRIPTION

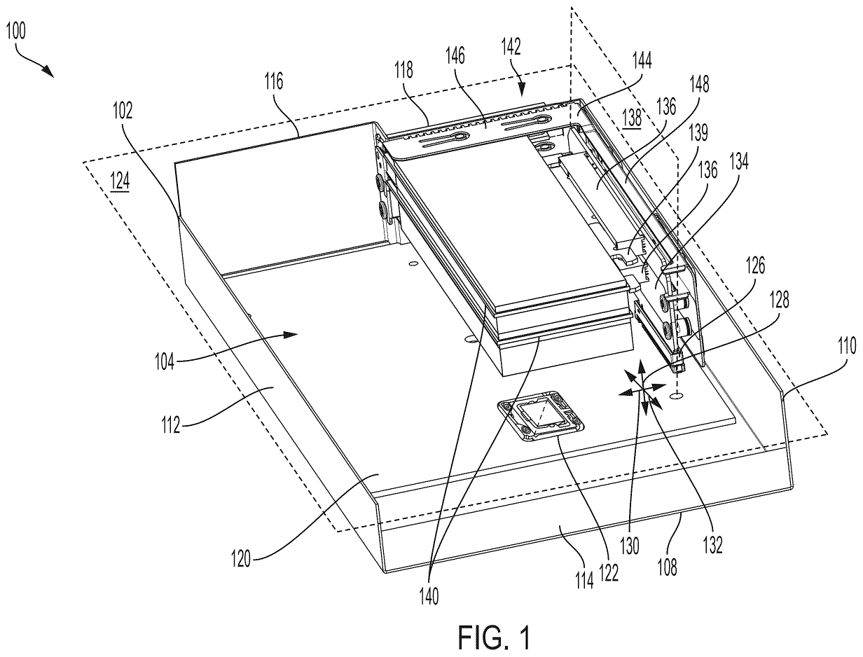

Now referring to the drawings, where whenever possible like reference numbers will refer to like elements, there is illustrated in FIG. 1 a computer system 100 comprised of various electronic devices and hardware that are cooperatively interconnected and assembled together and that may be accommodated in a common computer case referred to as a chassis 102. The chassis 102 can be a box-like structure made of formed sheet metal or molded plastic and that defines an internal space or chassis volume 104 for the internal computer components and electronic hardware of the computer system 100. The computer system 100 can be configured for communicative integration with a larger network or system and the chassis 102 may be designed for mounting into a rack with similar computer systems, although in other instances the computer system 100 may be a standalone configuration.

The chassis 102 can accommodate components and hardware devices like central processing units, memory modules, hard drives, power convertors, and fan units for circulating air internally in the chassis volume 104 for cooling of the internal components. The chassis 102 may be box-like and rectangular in shape and can include a planar base panel 108 and first and second upright side panels 110, 112 that extend perpendicularly from the planer base panel 108. To access the internal components in the chassis volume 104, the chassis 102 can include an upright front panel or I/O panel 116 that extends between the first and second upright side panels and which may include a plurality of I/O windows 118 or bays disposed therein. The I/O windows 118 enable the computer system 100 to interface with external cables for networking.

The chassis 102 can also include an upright rear panel 114 (in dashed lines) located opposite to the I/O panel 118 that may be configured to accommodate various LED indicator lights, activation and setting buttons and switches, ports and sockets for data and power communications, and other features for interfacing with operators and other systems. A removable cover may also be included to enclose the chassis volume 104. The chassis panels can be made of formed sheet metal or molded plastic structurally and rigidly connected together to provide the chassis 102 for support of the internal hardware components.

To mount and support the electronic devices and computing components, and for electrical connectivity, the chassis 102 can accommodate one or more printed circuit boards located internally in the chassis volume 104. For example, located in the chassis 102 can be a motherboard 120, also referred to as a mainboard or server board, on which one or more processors 122 or central processing units are mounted. The processors 122 can include electronic circuitry configured to conduct logical operations and may be implemented as an integrated circuit or chip. The motherboard 120 can also accommodate other core computing subsystems such as main memory, which may be embodied as a plurality of volatile random access memory modules in a DIMM format.

For surface mounting components onto the motherboard 120, the motherboard can be rigid and have a planar shape with opposing flat surfaces defining a planar board form 124. The motherboard 120 can be mounted directly to the base panel 108 of the chassis 102 so that the planar board form 124 is parallel thereto and orthogonal with respect to the first and second upright side panels 110, 112 and the I/O panel 116. The motherboard 120 can be rigidly fixed to the planar base panel 108 by a plurality of standoffs or spacers to provide separation or a gap therebetween for airflow.

For scalability, the computer system 100 can be expandable and provide for the integration of peripheral components and specialized or dedicated sub-systems. To connect with the peripheral systems, the motherboard 120 can include one or more expansion connectors mounted onto it. For example, a board-mounted expansion socket 126 located on the planer surface of the motherboard 120 is configured to connect with another printed circuit board in an orthogonal or perpendicular arrangement. To establish the orthogonal arrangement, the board-mounted expansion socket 126 defines an installation direction 128, in which the mating connector is moved for plugging, that is perpendicular to the planar board form 124. In the illustrated environment, the installation direction 128 is aligned parallel with the upright side panels 110, 112 and the I/O panel 116.

In addition to the installation direction 128, for reference purposes, the chassis 102 can be associated with a lateral direction 130 that extends between the first and second upright side panels 110, 112 and a longitudinal direction 132 that extends between the upright rear panel 114 and the forward I/O panel 116. The planar board form 124 of the motherboard 120 can be situated in the plane defined by the lateral and longitudinal directions 130, 132. To direct the expansion cards toward the I/O windows 118, the board-mounted expansion socket 126 can include an elongated socket slot extending in the longitudinal direction 132 and can be laterally offset adjacently toward, for example, the first upright side panel 110.

The board-mounted expansion socket 126 can be embodied as an edge connector that includes a socket slot disposed in an elongated insulative housing and that can receive the edge of the printed circuit card. The insulative housing of the edge connector includes spring-loaded contacts that bias against corresponding conductive traces on the planar surfaces at the edge of the printed circuit card, referred to a gold finger contacts, to established electronic communication between the components. When the printed circuit card, designated an expansion card or add-in card, is plugged into the board-mounted expansion socket 126, the card can extend perpendicularly to the planar board form 124 and can be directed toward the I/O panel 118.

In a computer system 100 that is expandable, such as a storage server or an application server, the number of expansion cards required may exceed the number of board-mounted expansion sockets 126 on the motherboard 120. To increase the connective capacity of the motherboard 120, a riser card 134 having additional card-mounted expansion sockets 136 can be connected to the board-mounted expansion socket 126. The riser card 134 can be a rigid printed circuit board having a flat planar card form 138 with a lower contact edge 139 having conductive traces or gold fingers along the periphery of the riser card that is adapted for insertion into the slot of the board-mounted expansion socket 126. When connected, the planar card form 138 of the riser card 134 is perpendicular to the planar board form 124 of the motherboard 120 and extends in the longitudinal direction 132 toward the I/O panel 116.

The plurality of card-mounted expansion sockets 136 mounted to the planar surface of the riser card 134 can be perpendicular or right-angled edge connectors similar to the board-mounted expansion socket 126 and therefore can accommodate similar expansion cards and add-in cards. The card-mounted expansion sockets 136 are perpendicular and therefore oriented for installation in the lateral direction 130. Accordingly, when an expansion card 140, which may also be a printed circuit card, is connected to the card-mounted expansion sockets 136 of the riser card 134, the expansion cards are parallel to the planar board form 124 of the motherboard 120. The horizontally-oriented expansion cards can be made longer and larger to include additional electronic devices and functionality.

The expansion cards 140 can be planar and rectangular in shape and can include a plurality of electronic components that are mounted onto it for expanding the functionality of the computer system 100. In an example, the expansion cards 140 can be configured as network interface cards having communication ports and communication jacks to interface with external systems. In another example, the expansion cards can be associated with additional data storage such as hard disk drives or solid state drives. The expansion cards 140 may also include additional processors such as graphic processing units.

To connect with external cables, the forward edges of the expansion cards 140 are located longitudinally adjacent to the I/O panel 116. Because the expansion cards 140 are parallel with the planar board form 124, the I/O windows 118 or bays disposed in the I/O panel 116 can be horizontal in alignment and extend in the lateral direction 130. Moreover, because of the increased capacity provided by the riser card 134, a plurality of expansion cards 140 can be vertically stacked in the installation direction 128.

To hold and fix the plurality of stacked expansion cards 140 in spatial relation to the I/O panel 116 and the riser card 134, the expansion cards and the riser card are operatively associated with a riser card assembly 142, which includes a riser card bracket 144 to interconnect the various parts of the assembly. The riser card bracket 144 is a L-shaped structure having a first leg, referred to as an I/O window brace 146 oriented in the lateral direction 130 and a second leg, designated as a chassis mounting support 148 extending in the longitudinal direction 132. The I/O window brace 146 and the chassis mounting support 148 perpendicularly intersect each other at a right angle to produce the L-shaped profile of the riser card bracket 144 and, when attached, extends along two intersecting edges of the expansion cards. The riser card bracket 144 can be made of formed or pressed sheet metal or molded plastic, and the intersecting I/O window brace 146 and the chassis mounting support 148 can integrally formed or joined via threaded fasteners such as sheet metal screws.

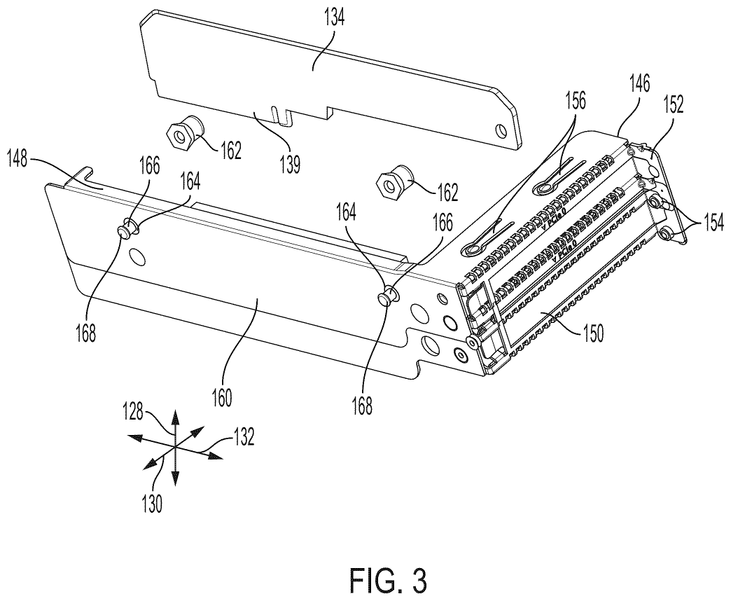

Referring to FIG. 3, the length of the I/O window brace 146 can be generally coextensive with the height of the expansion card and can be configured as a plate or frame having one or more expansion access slots 150 or cutouts through which the front edge of the expansion card can be exposed. The number of parallel expansion access slots 150, and thus the height of the I/O window brace 146 in the installation direction 128, corresponds to the number of expansion cards to be connected to the riser card.

To fixedly attach the riser card bracket 144 to the chassis, an attachment tab 152 can extend perpendicularly to the distal end of the I/O window brace 146 that can extend and overlap adjacent to a beam or column of the chassis and can be secured thereto with threaded fasteners. The attachment tabs 152 may have one or more keying features 154 such as slots or protrusions that interact with corresponding structures on the chassis for positioning and alignment of the riser assembly 142 during installation.

To attach to the expansion cards, the I/O window brace 146 can include retention features 156 such as cantilevered springs that can urge against the forward edge of the cards pressing them into alignment with the expansion access slots 150. In other embodiments, sheet metal screws can be directed through the I/O window brace 146 to secure the expansion cards.

The chassis mounting support 148 can have an extended support flat 160 that extends from the intersection with the I/O window brace 146 in the longitudinal direction 132 when installed and that may be configured as a flat straight board. The length of the extended support flat 160 in the longitudinal direction 132 can be commensurate with the length of the expansion cards. To attach to the riser card 134, one or more standoffs 162 or spacers can be located between the opposing planer faces of the riser card and the extended support flat 160. The standoffs 162 can be threaded adapters to rigidly and fixedly secure the riser card 134 and the chassis mounting support 148.

To releasably mount the riser card assembly 142 to the chassis or another fixed structure in the computer system, the riser card bracket 144 includes latching hardware that is located along the extended support flat 160 opposite of the attachment locations of the riser card standoffs 162. The latching hardware may be embodied as latch pins 164 that extend perpendicularly from the extended support flat 160 in the lateral direction 130 when the riser card assembly 142 is installed. The latch pins 164 can be cylindrical structures having a narrower pin body 166 and have an enlarged pin head 168 located at the distal end. The latch pins 164 can be spaced part in the longitudinal direction 132 to provide a plurality of attachment points for securely and firmly latching the riser card assembly 142. The latching pins 164 can be made of metal and attached to the extended flat support flat 160 by welding, riveting or similar attachment techniques.

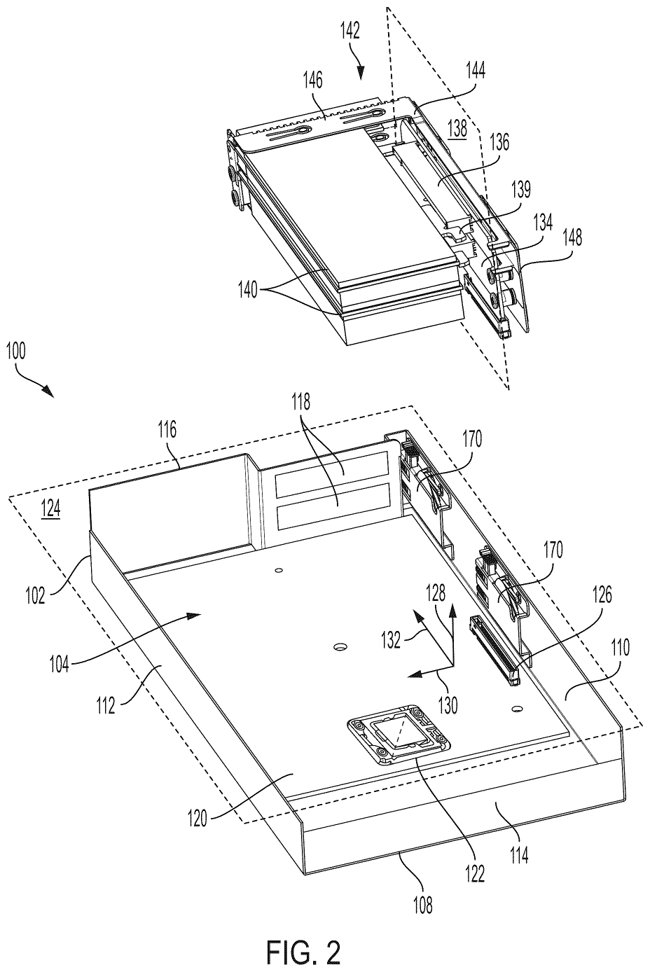

To securely install and/or remove the riser card assembly 142, the latch pins 164 can be an operative part of a releasably latching arrangement that may also include one or more latch mechanisms 170 as shown in FIG. 2. The latch mechanisms 170 can be fixedly mounted to the chassis in an orientation to engage the latch pins 164 when the riser card bracket 144 is moved in the installation direction 128 during installment. The latch mechanisms 170 can be designed to selectively lock and restrict movement of the latch pins 164 to spatially fixate the riser card assembly in relation to the chassis 102 and can be actuated to release the latch pins 164 for removal.

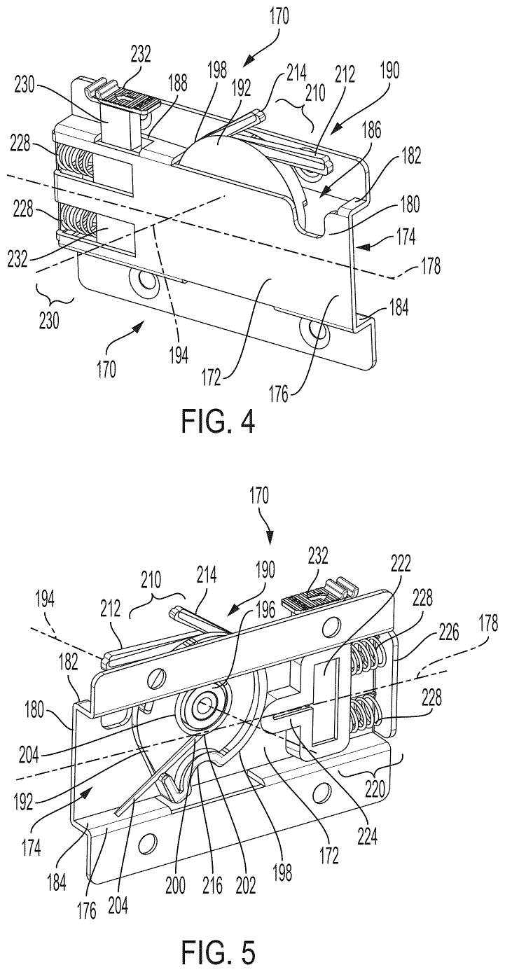

Referring to FIGS. 4 and 5, there is illustrated an example of a latch mechanism 170 that may be spring-actuated in accordance with the disclosure. The latch mechanism 170 can include a latch cover 172 formed from stamped and pressed metal plate material that defines a latch compartment 174. In the example, the latch cover 172 is formed as a C-shaped structural channel 176 having an elongated shape such that the latch compartment 174 extends along and defines a compartment axis 178. The latch cover 172 can be configured to mount internally and spatially fixate the moving internal parts of the spring-actuated latch mechanism 170

The structural channel 176 may include a planar channel web 180 that is rectangular in shape and that interconnects a pair of parallel, opposing channel flanges 182, 184 extending toward one side, perpendicularly from the longer edges of the channel web 180. The channel flanges 182, 184 define the sides of the latch compartment 174 and extend parallel with the compartment axis 178. One axial end of the latch compartment 174 can be generally opened and the other axial end may be blind and enclosed by an axial cover wall joined between the parallel channel flanges 182, 184. To attach the latch mechanism 170 to a structure, the distal ends of the channel flanges 182, 184 may be flared outwardly and may include holes or apertures through which fasteners can be inserted. The structural channel 176 can be made from a pressed and formed metal plate or from molded thermoplastic.

To access the latch compartment 174, a latch passageway 186 can be disposed in the latch cover 172 and can be oriented orthogonally toward the compartment axis 178. For example, the latch passageway 186 can be formed as a slot or cutout disposed into the first channel flange 182 and may also include a pin notch disposed into the channel web 180 that is shaped for receiving the latch pins. Also disposed as a cutout into the first channel flange 182 can be button slot 188 that is parallel with the compartment axis 178. The latch passageway 186 and the button slot 188 can be disposed toward axially opposite ends of the latch cover 172.

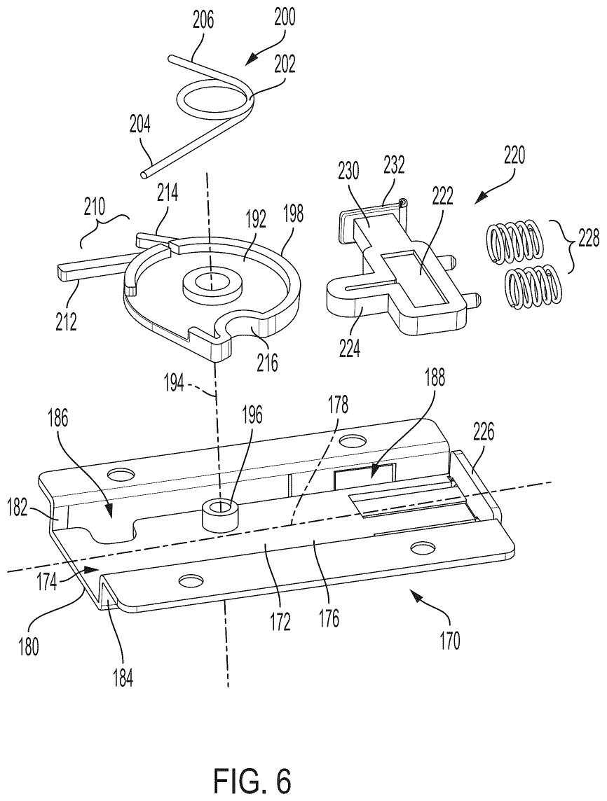

Referring additionally to FIG. 6, to physically lock and release the latch pin, the latch mechanism 170 includes a spring-loaded actuator 190 that is partially accommodated in the latch compartment 174 defined by the latch cover 172. In an example, the spring-loaded actuator 190 include a latch rotor 192 formed from a structural circular disk made of metal or plastic. The latch rotor 192 can be rotationally mounted to the latch cover 172 inside the latch compartment 174 and can rotate with respect to a rotational axis 194 extending through the center of the structural circular disk. When mounted to the latch cover 172, the rotational axis 194 can extend perpendicular to the channel web 180. To rotationally attach the latch rotor 192 to the latch cover 172, a rotor axle 196 can be fixed to and extend perpendicularly from the channel web 180 and can form a journal bearing with a central hole or aperture formed in the structural circular disk. The latch rotor 192 may also include a generally circular rotor periphery 198 concentrically aligned to the rotational axis 194.

To rotationally actuate the latch rotor 192 about the rotational axis 194, the spring-loaded actuator 190 is operatively associated with an elastic spring 200 such as, for example, a helical torsion spring. Embodied as a helical torsion spring, the spring 200 includes a long stiff wire partially wound into a helical coil 202 aligned with the rotational axis 194. The helical coil 202 can be disposed around the rotor axle 196 and can include two angular spaced spring legs including a first leg or static leg 204 and a second leg or deflecting leg 206. The static leg 204 can extend radially beyond the rotor periphery 198 to contact the second channel flange 184.

The deflecting leg 206 can extend radially from the helical coil 202 to contact the inner rim of the rotor periphery 198 where it can be received and restrained in spring notch 208. The static and deflecting legs 204, 206 of the spring 200 can angular deflect together and apart with respect to the helical coil 202 that is concentrically situated with the rotational axis 194 of the latch rotor 192. When the latch rotor 192 is mounted to the latch cover 172, the latch rotor can be rotated about the rotational axis 194 by compression and extension of the helical torsion spring 200.

For example, because the deflecting leg 206 is restrained by the spring notch 208 on the rotor periphery 198 and the static leg 204 abuts against the second channel flange 184, when latch rotor 192 is caused to rotate about the rotational axis 178 in the counter-clockwise direction by an applied force, the helical torsion spring 200 is compressed. When the applied force ceases, the stored energy in the helical coil 202 biases the static leg 204 and the deflecting leg 206 to angularly expand thereby rotating the latch rotor 190 in the clockwise direction.

To interact with the latch pin, which may be associated with the applied force, the latch rotor can include a catch 210 formed on the rotor periphery 198 and that may be locationally proximate to the latch passageway 186. The catch 210, in an example, may be formed by a pair of bifurcated cog prongs 212, 214 that angularly diverge from each other and that extend generally tangentially from the rotor periphery 198. The bifurcated cog prongs 212, 214 form a forked structure of the catch 210 that are adapted to extend alongside about and constrain the latch pin therebetween when moved appropriately. The bifurcated cog prongs 212, 214 can extend outward from the latch passageway 186 when the helical torsion spring 200 is expanded, rotating the latch rotor 192 clockwise and the spring-loaded actuator 190 is in a released state. The catch 210 can have other shapes and configurations such as a hook or, for example, the catch 210 can be formed as a concaved notch cut into the rotor periphery 198 of the latch rotor 192.

In addition to the catch 210, the latch rotor 192 can include a detent 216 that is formed into the rotor periphery 198. The detent 216 may have a curved shaped. The catch 210 and the detent 216 can be angularly spaced apart from each other, approximately diametrically opposite each other with respect to the rotational axis 194 of the latch rotor 192.

To restrain rotation of the latch rotor 192 about the rotational axis 174 due to urging of the torsion spring 200, the latch mechanism 170 includes a spring-loaded stopper 220 that is slidingly movable within the latch compartment 174. The slidingly movable spring-loaded stopper 220 can be structurally shaped as a T and can have a stopper bar 222 that extends between the first and second channel flanges 182, 184 perpendicular to the compartment axis 178 and a plunger prong 224 that is joined perpendicularly to the stopper bar 222. The plunger prong 224 can extend parallel to the compartment axis 178 when the spring-loaded stopper 220 is disposed in the latch compartment 174 and can be directed toward the spring-loaded actuator 190 and perpendicular to the rotational axis 194.

The distal end of the plunger prong 224 can be rounded and shaped to fit into the detent 216 that is formed on the rotor periphery 198 of the latch rotor 192. For example, the detent 216 can be formed as a concaved notch cut into the rotor periphery 198. When the latch rotor 192 rotates about the rotational axis 194, the detent 216 can be rotated into alignment with the plunger prong 224 with respect to the compartment axis 178. The correspondingly shaped distal end of the plunger prong 224 is received into the detent 216 interlocking the latch rotor 192 and the spring-loaded stopper 210.

To urge the plunger prong 224 against the rotor periphery 198, the spring-loaded stopper 220 can include one or more coil springs 228, which may be produced from a helically wound coil of spring steel and which can expand and contract along a deflecting axis when under tension or compression. To retain the coil springs 228 in the latch compartment 174, one axial end of the latch channel 176 can be blinded by an axial channel wall 226 that extends between the first and second channel flanges 182, 184 and that is traverse to the compartment axis 178.

The coil springs 228 are located between the stopper bar 222 and the axial channel wall 226 and are oriented so their deflection axis is parallel with the compartment axis 178. The coil springs 228 urge the plunger prong 224 against the rotor periphery 198 and into the detent 216 when aligned. To cause the spring-loaded stopper 220 to translate evenly with respect to the compartment axis 178, two coil springs 228 can be included to evenly balance the spring forces applied to the stopper bar 212, however, different numbers of coil springs 228 can be included with the latch mechanism 170.

To move the spring-loaded stopper 220 within the latch compartment 174 by hand, a slider button 230 can be attached to an end of the stopper bar 222, perpendicular to the compartment axis 178, and the slider button 230 can extend through the slider slot 188 disposed through the first channel flange 182. Formed on the distal end of the slider button 230, exteriorly of the latch cover 172, can be a thumb pad 232 shaped for pressing the slider button 230 along the latch axis 178. When a force is applied to the slider button 230 aligned in the compartment axis 178, the stopper bar 222 fixed to the slider button 230 can be caused to move within the latch compartment 1734 axially along the direction of compartment axis 178.

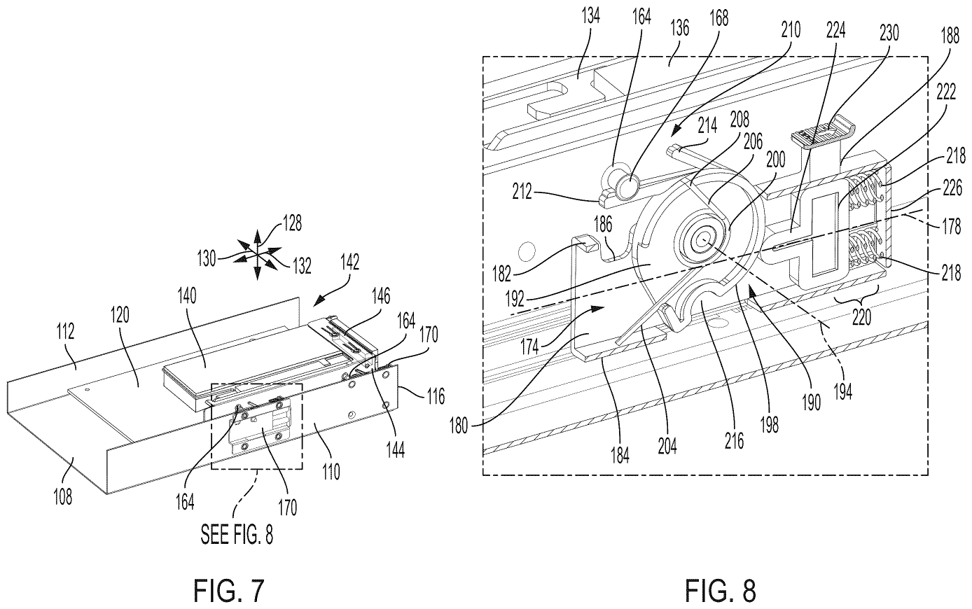

Referring to FIG. 7, prior to installation, the latching mechanisms 170 can be mounted within the chassis 102 in various appropriate locations relative to the motherboard 120. For example, a pair of latch mechanisms 170 may be mounted to the first side panel 110 of the chassis 102 to be spaced apart in the longitudinal direction 132 and can be situated above the motherboard 120 and the board-mounted expansion socket 126 in the installation direction 128. The latch mechanisms 120 are thus in a spatially fixed relations to the chassis 102 and motherboard 120. However, in other computer systems 120, the latch mechanism 170 can be mounted to another intermediate chassis panel or another fixed structure of the chassis. Although the illustrated embodiment includes two latch mechanisms 170, any suitable number can be used in the disclosed latching arrangement.

Also prior to installation, the riser card assembly 142 can be assembled by attaching the riser card 134 to the riser card bracket 144 and connecting one or more expansion cards 140 to the riser card 134. The planar card form 138 of the riser card 134 may be perpendicular to the expansion cards 140, which are installed in the lateral direction 130 to the riser card 134. The latch pins 164 extending from the chassis mounting support 148 can also be aligned in the lateral direction 130 when the riser card assembly 142 is prepared for installation.

The riser card assembly 142 is positioned with respect to the chassis 102 so that the one or more latch pins 164 align with the one or more latch mechanisms 170 in the installation direction 128. The pitch or spread between the latch mechanisms 170 in the traverse direction 132 can be configured to align the lower contact edge 139 of the riser card 134 with the board-mounted expansion socket 126 on the motherboard 120. Accordingly, when the riser card assembly 142 is moved with respect to the chassis 102 in the installation direction 128, the lower contact edge of the riser card 134 is inserted into the board-mounted expansion socket 126 and the latch pins 164 of the riser card bracket 144 interface with the latch mechanisms 170 mounted on the chassis 102. Preferably, the I/O window brace 146 of the riser card bracket 144 may also align with the I/O panel 116 of the chassis in the longitudinal direction 132.

Referring to FIG. 8, the latch pin 164 can be aligned with the latch passageway 186 of the latch cover 172 in the installation direction 128. However, when the latch mechanism 170 is in the released state, the torsion spring 200 expands to rotate the latch rotor 192 about the rotational axis 194 and moves the longer cog prong 212 of the bifurcated catch 210 parallel with the first channel flange 182 over the latch passageway 186, and thus blocking access to the latch compartment 172. The latch pin 164 therefore contacts the longer cog prong 212, the cross-section of the longer cog prong 212 can be sized to fit between the pin head 168 and the extended support flat 160 of the latch pin 164 that is created by the narrower pin body 166.

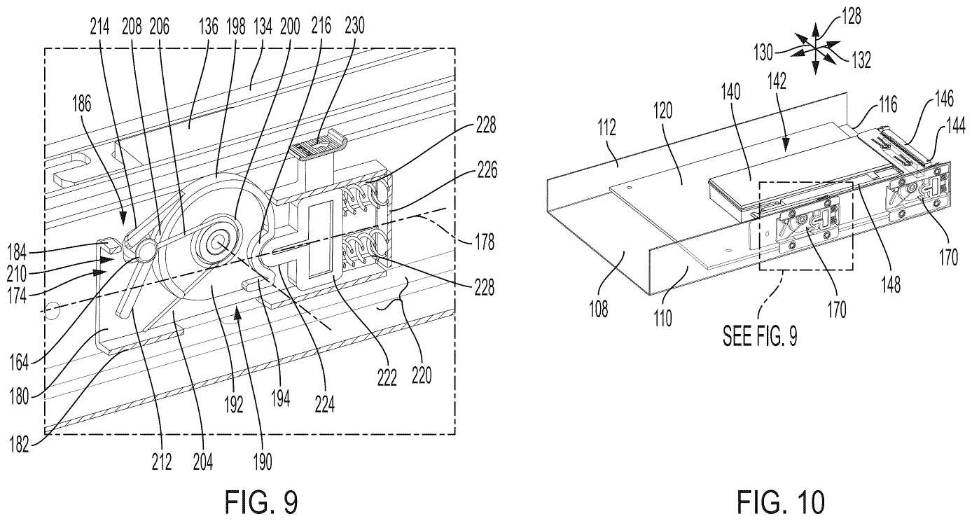

Referring to FIGS. 9 and 10, application of a sufficient installation force to the riser card assembly 142 moves and presses the latch pin 164 and displaces the abutting longer cog prong 212 in the installation direction 128 into the latch passageway 186. Because the longer cog prong 212 extends from the rotor periphery 198, displacement of the longer cog prong 212 causes the latch rotor 192 to rotate in the clockwise direction with respect to the rotational axis 194. Rotation of the latch rotor 192 also causes the deflecting leg 206 of the torsion spring 200, that is fixed at its distal end to the spring notch 208 on the rotor periphery 198, to angularly deflect toward the static leg 204 abutting the second channel flange 184 of the channel cover 172, compressing the torsion spring 200.

Continued linear movement of the latch pin 164 into the latch passageway 186 with respect to the installation direction 128, and the resulting rotation of the latch rotor 192 about rotational axis 194 in the counter-clockwise direction, will rotate the catch 216 on the rotor periphery into alignment with the plunger prong 224 on the spring-loaded stopper 220 aligned with respect to the compartment axis 178. The coil springs 228 urge the stopper bar 222 to axially translate in the compartment axis 178 to insert the plunger prong 224 into the correspondingly shaped detent 216.

Interaction of the detent 216 and the plunger prong 224 restrains further rotation of the latch rotor 192 in either direction and hence the spring-loaded stopper 220 restrains and arrests movement of the spring-loaded actuator 190. Engagement of the detent 216 and plunger prong 224 likewise resists angular expansion of the static leg 204 and deflecting leg 206 maintaining the torsion spring 200 in compression.

Moreover, the angular alignment between the detent 216 and the plunger prong 224 may be set so that the shorter cog prong 214 is positioned downwardly into the latch passageway 186 such that the latch pin 168 is captured by the angularly diverging bifurcated longer and shorter cog prongs 212, 214 of the catch 210, thereby obstructing movement of the latch pin 164. This may be referred to as the locked state. The latch pin 210 is thus restrained by the spring-loaded actuator 190 and is locked to the latch mechanism 170.

Referring to FIG. 10, when the latch pins 164 and the latch mechanisms 170 are in the locked state, the riser card 134 may be plugged into the board-mounted connector socket and the riser card assembly 142 can be flush with the first upright side panel 110 of the chassis 102. Further, the slider buttons 230 can be accessible at the interface between the extended support flat 160 of the riser card bracket 144 and the first upright side panel 110. To release the riser card assembly 142 from the computer system 100, the slider buttons 230 is moved in the longitudinal direction 132, removing the plunger prong 224 from the detent 216 and releasing the torsion spring 200 to rotate the latch rotor 192 and eject the latch pin 164.

Referring to FIG. 9, moving the slider button 230 in the longitudinal direction 132 consequentially moves the stopper bar 222 along the compartment axis 178 compressing the coil springs 228. The plunger prong 224 is removed from the detent 216 in the rotor periphery 198, releasing the latch rotor 192, and the compressed torsion spring 200 is released to cause rotation of the latch rotor 192 clockwise about the rotational axis 194. The bifurcated cog prongs 212, 214 of the catch 210 move outwardly of the latch passageway 186 ejecting the latch pin 164 from the latch compartment 174 and releasing riser card assembly 142 from the latch mechanism 170. The spring force released from the compressed torsion spring 200 can assist in removing and uninstalling the riser card assembly 142 by ejecting the latch pins 164.

The disclosure provides a latch mechanism that can stably and releasably lock a riser card assembly within a computer system so that the riser cards cannot unintentionally disconnect from the mother board. The latch mechanisms allow for tool-free and removal, meaning that the riser card assembly can be installed without the use of a screwdriver or other fastening tools and components simplifying assembly. While the disclosed computer system utilized two latch mechanisms to secure and stabilize the riser card assembly to the chassis panel, the number and arrangement may be different. Moreover, the riser card bracket used with the latch mechanisms can have different shapes and configurations for supporting the latch pins. Furthermore, to remove and uninstall the riser card assembly, the latch mechanism includes a slidable button that is positioned in a readily accessible location in relation to the riser card bracket. When pressed by hand, the slidable button releases the riser card assembly from the latch mechanism.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A computer system comprising:
a chassis;
a motherboard having a planar board form located in the chassis and having a board-mounted expansion socket that defines an installation direction perpendicular to the board form;
a riser card assembly comprising a riser card having a planar card form perpendicular to the planar board form and one or more card-mounted expansion sockets;
a riser card bracket that is attached to the riser card, the riser card bracket comprising a latch pin that extends in a lateral direction perpendicular to the installation direction;
a latch mechanism mounted to a chassis panel, the latch mechanism comprising:
a latch cover defining a latch compartment extending in a compartment axis, the latch compartment accessible through a latch passageway disposed in the latch cover;
a spring-loaded actuator defining a catch and a detent, the catch configured to receive and retain the latch pin when the latch pin is moved in the installation direction into the latch passageway; and
a spring-loaded stopper biased against the spring-loaded actuator to engage the detent and restrain the spring-loaded actuator.

2. The computer system of claim 1, wherein the spring-loaded actuator comprises a latch rotor having a rotational axis aligned parallel to the lateral direction.

3. The computer system of claim 2, wherein the spring-loaded actuator comprises a torsion spring having a helical coil concentric to the rotational axis and a pair of angular-spaced spring legs including a static leg and a deflecting leg.

4. The computer system of claim 3, wherein the latch rotor comprises a rotor periphery, and the static leg extends beyond the rotor periphery to abut the latch cover.

5. The computer system of claim 4, wherein the deflecting leg extends to and is retrained at the rotor periphery.

6. The computer system of claim 1, wherein the catch comprises a pair of bifurcated cog prongs that angularly diverge from each other.

7. The computer system of claim 6, wherein the pair of bifurcated cog prongs normally passes through the latch passageway when the spring-loaded actuator is released.

8. The computer system of claim 1, wherein the latch compartment extends along a compartment axis and the latch passageway is orthogonal to the compartment axis.

9. The computer system of claim 8, wherein the spring-loaded stopper is biased to translate in parallel along the compartment axis.

10. The computer system of claim 9, wherein the spring-located stopper includes one or more coils springs having a deflection axis parallel to the compartment axis.

11. The computer system of claim 10, wherein the spring-loaded stop includes a plunger prong shaped to be received in the detent.

12. The computer system of claim 1, wherein the riser card bracket includes an I/O window brace and a chassis mounting support perpendicularly intersected to each other and the latch pin is attached to the chasing mounting support.

13. The computer system of claim 1, wherein the riser card comprises one or more card-mounted expansion sockets that define a second installation direction parallel to the lateral direction and perpendicular to the first installation direction.

14. A method of installing a riser card assembly into a computer system comprising:
providing a riser card bracket comprising one or more latch pins extending in a lateral direction;
attaching a riser card to the riser card bracket to produce a riser card assembly, the riser card comprising a card-mounted expansion socket oriented in the lateral direction and a lower contact edge oriented in an installation direction perpendicular to the lateral direction;
installing the riser card assembly to a board-mounted expansion socket by moving the riser card assembly in the installation direction to concurrently:
insert the lower contact edge into the board-mounted expansion socket;
insert the latch pin into a latch passageway of a latch mechanism mounted to a chassis of the computer system to actuate a spring-loaded actuator of the latch mechanism to retain the latch pin, and
restraining the spring-loaded actuator with a spring-load stopper to retrain the latch pin.

15. The method of claim 14, wherein the latch pin is inserted into the latch passageway in the installation direction.

16. The method of claim 15, wherein the spring-loaded stopper is biased to translate along a compartment axis of the latch mechanism orthogonal to the installation direction.

17. The method of claim 14, wherein the spring-loaded actuator includes a torsion spring having a static leg and a deflecting leg that are angularly compressible to each other during installation.

18. The method of claim 17, further comprising connecting an expansion card to a card-mounted expansion socket by moving the expansion card in the lateral direction.

19. A latch mechanism for installing printed circuit cards in a computer system comprising:
a latch cover defining a latch compartment extending along a compartment axis, the latch compartment accessible by a latch passageway orthogonal to the compartment axis;
spring-loaded actuator partially located in the latch compartment, the spring-loaded actuator comprising a catch configured to receive a latch pin moved toward the latch passageway and orthogonally to the compartment axis; and
a spring-loaded stopper biased to translate along the compartment axis against the spring-loaded actuator to engage a detent and restrain the spring-loaded actuator.

20. The latch mechanism of claim 19, wherein the spring-loaded actuator includes a latch rotor having circular periphery with the catch and the detent located on the circular periphery, and the spring-loaded actuator further includes a torsion spring having a rotational axis orthogonal to latch axis to rotate the latch rotor; and
the spring-loaded stopper includes a plunger prong shaped to be received in the detent and the one or more coil springs having a deflection axis parallel to the compartment axis to urge the plunger prong against the rotor periphery.
